(19) United States
(12) Patent Application Publication
(10) Pub. No.: US 2007/0194336 A1
(43) Pub. Date: Aug. 23, 2007

(54) Light emitting device package and method of manufacturing the same

(75) Inventors: Su-ho Shin, Seongnam-si (KR); Kyu Ho Shin, Seoul (KR); Jin-seung Choi, Suwon-si (KR); Soon Cheol Kweon, Seoul (KR); Seung-tae Choi, Suwon-si (KR); Ki-hwan Kwon, Suwon-si (KR); Chang Youl Moon, Suwon-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/520,834

(22) Filed: Sep. 14, 2006

(30) Foreign Application Priority Data
Feb. 17, 2006 (KR) 10-2006-0015402

(51) Int. Cl. H01L 33/00; H01L 21/00

(52) U.S. Cl. 257/98; 257/99; 438/27; 257/E33.075

(57) ABSTRACT

A light emitting device package including: a heat dissipating substrate including a cavity; a first conductive pattern formed on the cavity; a light emitting device installed on the first conductive pattern; and a second conductive pattern formed on the heat dissipating substrate at a periphery of the first conductive pattern. The second conductive pattern is electrically separated from the first conductive pattern, and the first and second conductive patterns supply power required for operating the light emitting device.

### CROSS-REFERENCE TO RELATED APPLICATIONS

This application claims priority from Korean Patent Application No. 10-2006-0015402, filed on Feb. 17, 2006, in the Korean Intellectual Property Office, the disclosure of which is incorporated herein by reference.

### BACKGROUND OF THE INVENTION

1. Field of the Invention

Apparatuses and methods consistent with the present invention relate to a light emitting device package capable of improving a heat dissipating function and simplifying an entire structure and a manufacturing process to reduce a manufacturing cost and improve productivity.

2. Description of the Related Art

Generally, light emitting diodes are widely used as light sources due to their low power consumption and high brightness. Recently, light emitting diodes have been employed as lighting devices and a backlight devices for LCDs. Light emitting diodes are provided in a package which is easy to install in all kinds of devices such as lighting devices. There are a number of requirements for a light emitting device package, including protecting the light emitting diode, electrically connecting the device, and dissipating and radiating heat generated by the light emitting diode.

Particularly, heat dissipation and radiation is an important characteristic in fields which requires high power light emitting diodes.

Namely, since the performance and lifespan of a light emitting diode in a light emitting device package may exponentially decrease as an operation temperature of the light emitting diode increases, and the light emitting diode may become discolored as the operation temperature rises above a certain value, heat generated from the light emitting diode must be sufficiently radiated to maintain an optimal operation temperature. Accordingly, a light emitting device package having a simple structure and an improved heat dissipating function to increase performance and lifespan is required.

### SUMMARY OF THE INVENTION

According to an exemplary embodiment of the present invention, there is provided a light emitting device package including: a heat dissipating substrate including a cavity; a first conductive pattern disposed on the cavity; a light emitting device disposed on the first conductive pattern; and a second conductive pattern disposed on the heat dissipating substrate at a periphery of the first conductive. The second conductive pattern is electrically separated from the first conductive pattern, and the first conductive pattern and the second conductive pattern supply power required for operating the light emitting device.

The heat dissipating substrate may be formed of various materials such as a metal having a high thermal conductivity, and may have an insulating layer formed on a surface thereof. The heat dissipating substrate may be formed in various shapes and sizes. For example, the heat dissipating substrate may be formed of aluminum or an aluminum alloy, and an oxidized layer may be formed on the surface of the heat dissipating substrate by an anodizing process or a polymer based insulating layer. The light emitting device may be installed in a cavity of the heat dissipating substrate so that heat generated when the light emitting device operates is emitted directly via the heat dissipating substrate, thereby reducing thermal resistance and improving a heat dissipating performance.

The light emitting device may be a light source device which itself generates, such as a light emitting diode. The number and a structure of the light emitting device may vary.

The first conductive pattern may include a reflective surface acting as a conductor and a reflector. The reflective surface may be formed by disposing a reflective coating layer formed of a reflective material, on the first conductive pattern. A connecting conductive pattern may be electrically connected to the first conductive pattern. The connecting conductive pattern may be formed by being extended from the first conductive pattern.

A heat sink for improving a heat dissipating performance may be formed in a single body with the heat dissipating substrate. An opening portion of the cavity may be covered by a lens. Various lenses may be used as the lens, as would be understood by one of skill in the art. Also, a transparent resin may fill a space between the cavity and the lens.

According to another exemplary embodiment of the present invention, a method of manufacturing a light emitting device package includes: providing a heat dissipating substrate having a cavity therein; forming a first conductive pattern on the cavity; forming a second conductive pattern on the heat dissipating substrate at a periphery of the first conductive pattern; and installing a light emitting device on the first conductive pattern. The second conductive pattern is electrically separated from the first conductive pattern.

### BRIEF DESCRIPTION OF THE DRAWINGS

The above and/or other exemplary aspects and advantages of the present invention will become apparent from the following detailed description of exemplary embodiments of the present invention, taken in conjunction with the accompanying drawings of which:

FIG. 1 is a perspective view illustrating a light emitting device package according to a first exemplary embodiment of the present invention;

FIG. 2 is a cross-sectional view illustrating the light emitting device package according to the first exemplary embodiment of the present invention;

FIGS. 3 and 4 are cross-sectional views illustrating examples light emitting device package according to the first exemplary embodiment of the present invention;

FIG. 5 is a cross-sectional view illustrating a light emitting device package according to a second exemplary embodiment of the present invention;

FIG. 6 is a cross-sectional view illustrating a light emitting device package according to a third exemplary embodiment of the present invention;

FIG. 7 is a perspective view illustrating a light emitting device package according to a fourth exemplary embodiment of the present invention;

FIG. 8 is a perspective view illustrating a light emitting device package according to a fifth exemplary embodiment of the present invention;

FIG. 9 is a cross-sectional view illustrating the light emitting device package according to the fifth exemplary embodiment of the present invention;

FIG. 10 is a perspective view illustrating a light emitting device package according to a sixth exemplary embodiment of the present invention;

FIG. 11 is a perspective view illustrating a light emitting device package according to a seventh exemplary embodiment of the present invention;

FIGS. 12 and 13 are perspective views illustrating a light emitting device package according to an eighth exemplary embodiment of the present invention;

FIG. 14 is a perspective view illustrating a light emitting device package according to a ninth exemplary embodiment of the present invention;

FIG. 15 is a perspective view illustrating a light emitting device package according to a tenth exemplary embodiment of the present invention;

FIGS. 16 through 18 illustrate a method of manufacturing a light emitting device package according an exemplary embodiment of the present invention; and

FIG. 19 illustrates a method of manufacturing a light emitting device package according to another exemplary embodiment of the present invention.

### DETAILED DESCRIPTION OF EXEMPLARY EMBODIMENTS OF THE INVENTION

Reference will now be made in detail to the exemplary embodiments of the present invention, examples of which are illustrated in the accompanying drawings, wherein like reference numerals refer to the like elements throughout. The exemplary embodiments are described below to explain the present invention by referring to the figures.

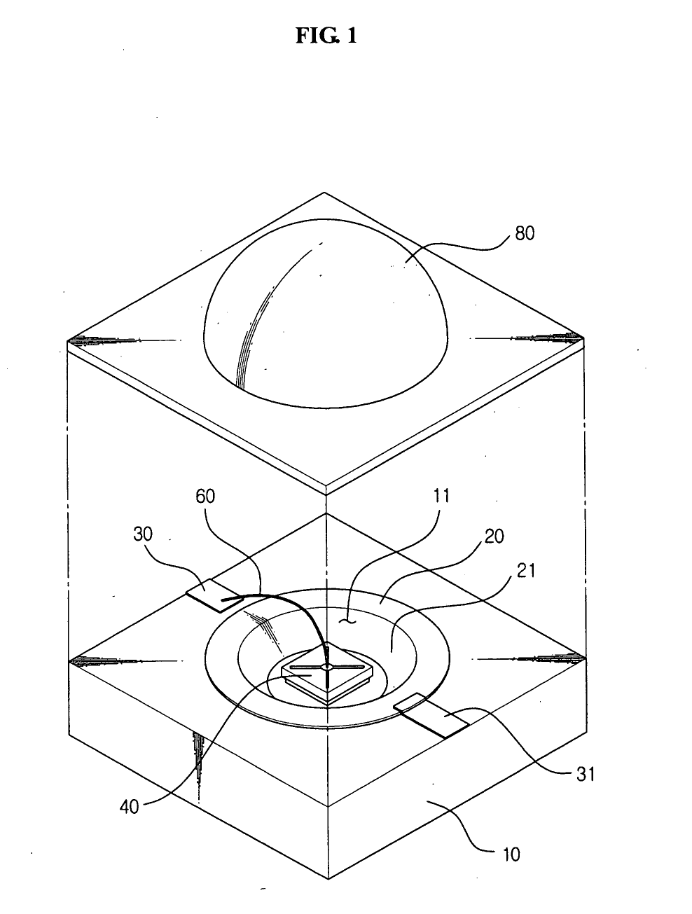

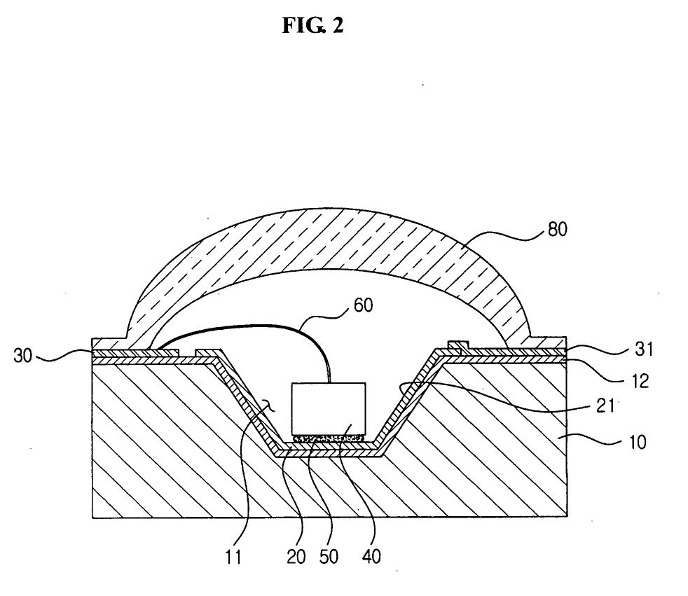

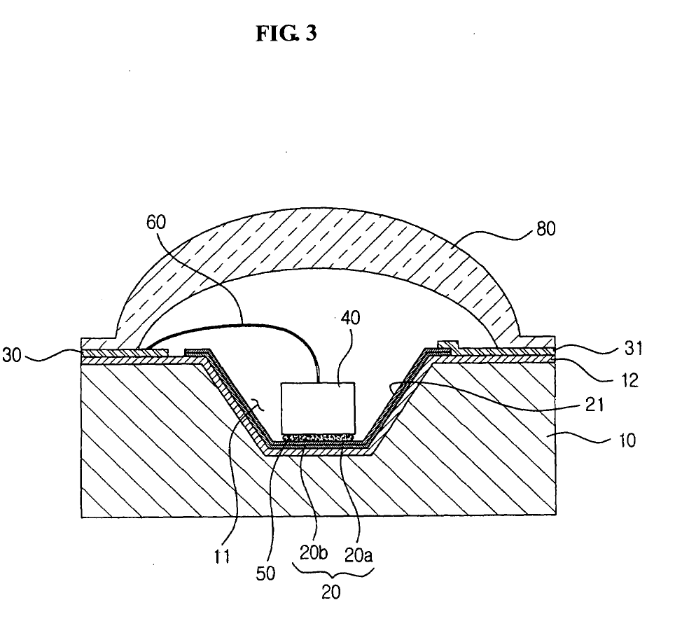

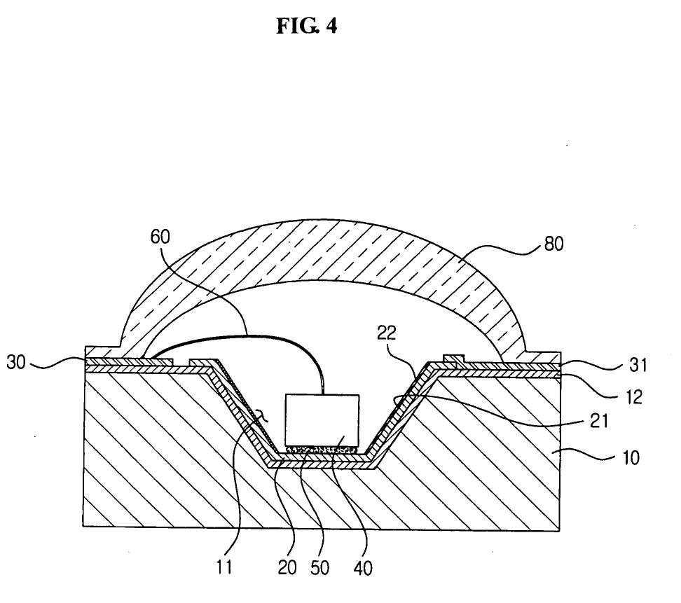

FIG. 1 is a perspective view illustrating a light emitting device package according to a first exemplary embodiment of the present invention, and FIG. 2 is a cross-sectional view illustrating the light emitting device package according to the first exemplary embodiment of the present invention. Also, FIGS. 3 and 4 are cross-sectional views illustrating examples of a first conductive pattern of the light emitting device package according to the first exemplary embodiment of the present invention.

In describing exemplary embodiments of the present invention, well-known functions or configurations may be omitted to clearly describe the present invention.

As shown in FIGS. 1 and 2, the light emitting device package according to the present exemplary embodiment includes a heat dissipating substrate 10 including a cavity 11, a first conductive pattern 20 on the cavity 11, a light emitting device 40 installed on the first conductive pattern 20, and a second conductive pattern 30 formed on a periphery of the first conductive pattern 20 to be electrically separated from the first conductive pattern 20 and supplying power required for operating the light emitting device 40 together with the first conductive pattern.

The heat dissipating substrate 10 is formed of a metal having a high thermal conductivity, and an insulating layer 12 is formed on a surface of the heat dissipating substrate 10. The cavity 11 having a predetermined size is formed to be sunk into a top of the heat dissipating substrate 10. In the present exemplary embodiment, the cavity 11 has a cross-section which expands toward the surface of the heat dissipating substrate 10. However, the cavity may be formed in other shapes according to circumstances.

The heat dissipating substrate 10 may be formed of aluminum or an aluminum alloy. The cavity may be formed by mechanical processing or etching.

The insulating layer 12 may be an oxidized layer formed by an anodizing process on the heat dissipating substrate 10 formed of aluminum or an aluminum alloy. According to circumstances, an additional polymer based insulating layer may be formed on the surface of the heat dissipating substrate 10. However, since the oxidized layer has a relatively high thermal conductivity and a small thickness, a low thermal resistance may be embodied.

The first conductive pattern 20 is formed of a single layer or multiple layers of a conductive material such as aluminum, copper, chrome, titanium, platinum, or silver, and is formed on a top surface of the insulating layer 12, corresponding to a bottom surface and a side of the cavity 11. Namely, the first conductive pattern 20 may be formed of a single metal layer as shown in FIG. 2 or may be formed of multiple metal layers 20a and 20b as shown in FIG. 3. Hereinafter, an example of forming a part of the first conductive pattern 20 to cover a top surface of the heat dissipating substrate 10 will be described.

A surface of the first conductive pattern 20 may be formed of a reflective surface 21. According to circumstances, as shown in FIG. 4, the reflective surface 21 may be provided by forming a reflective coating layer 22 of a reflective material, such as silver, on a top surface of the first conductive pattern 20.

On the top surface of the insulating layer 12, corresponding to the top surface of the heat dissipating substrate 10, a connecting conductive pattern 31 may be formed to be electrically connected to the first conductive pattern 20. The conductive pattern 31 may be a single layer or multiple layers of an electro-conductive material, similar to the material of the first pattern, such as aluminum, copper, chrome, titanium, platinum, and silver.

The light emitting device 40 is a light source device which generates light, such as a light emitting diode, and is installed on the first conductive pattern 20 and electrically connected thereto.

The electrical connection between the light emitting device 40 and the first conductive pattern 20 may be embodied by an electro-conductive adhesive layer 50 interposed between the light emitting device 40 and the first conductive pattern 20. The electro-conductive adhesive layer 50 may be formed of an electro-conductive material such as solder- or epoxy-based conductive adhesives.

The second conductive pattern 30 is formed on the top surface of the insulating layer 12, corresponding to the top surface of the heat dissipating substrate 10, and is electrically connected to the light emitting device via a first bonding wire 60. The second conductive pattern may be formed of an electro-conductive material, similar to the material of the first conductive pattern, and is electrically separated from the first conductive pattern.

A lens 80, which covers an opening portion of the cavity 11, may be coupled to the heat dissipating substrate 10. The lens 80 enables the light emitted from the light emitting device 40 to be emitted more effectively. In the present exemplary embodiment, the lens 80 is a convex lens. However, according to any required optical properties, lenses of various forms may be applied.

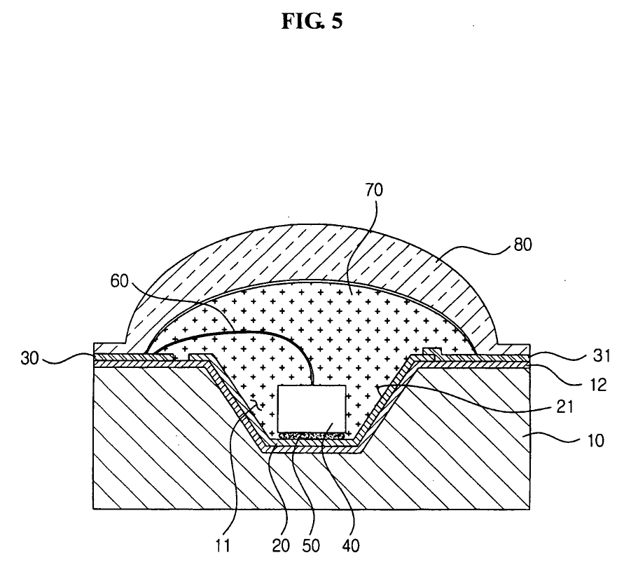

FIG. 5 is a cross-sectional view illustrating a light emitting device package according to a second exemplary embodiment of the present invention. As shown in FIG. 5, a transparent resin 70 fills a space between the heat dissipating substrate 10 including the cavity 11, and the lens 80, to protect the light emitting device 40. A fluorescent material may be mixed with the transparent resin 70 to convert the wavelength of the light emitted from the light emitting device 40.

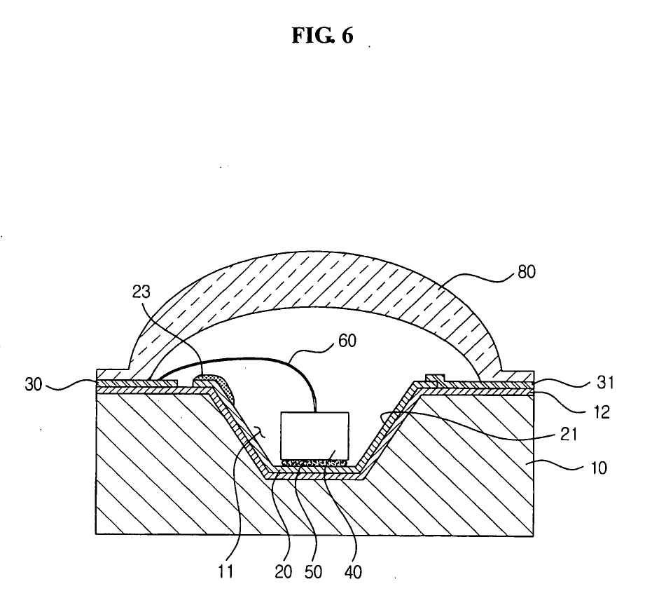

FIG. 6 is a cross-sectional view illustrating a light emitting device package according to a third exemplary embodiment of the present invention. As shown in FIG. 6, a protection layer 23 which insulates the first bonding wire from the first conductive pattern may be formed on the surface of the first conductive pattern 20 or the surface of the first bonding wire 60. Hereinafter, an example of forming the protection layer 23 on a part of the surface of the first conductive pattern 20 will be described.

The light emitting device 40 has a vertical electrode structure and is electrically connected to the first and the second conductive patterns 20 and 30. Power is supplied to the light emitting device 40 via the first and second conductive patterns 20 and 30, and light from the light emitting device 40 is emitted to the outside.

As described above, the light emitting device 40 is directly installed in the cavity formed on the heat dissipating substrate 10. Also, the heat dissipating substrate is made of metal. Thereby, the size and number of components and manufacturing processes may be reduced, and a heat dissipating function is improved as compared to a conventional structure of a light emitting device package in which a light emitting device is separately installed to an additional metal core printed circuit board (MCPCB).

In conventional technology, a light emitting device package, in which the light emitting device is separately installed, is installed on the additional MCPCB, and heat generated from the light emitting device is transferred to the MCPCB via a thermal interface material (TIM) and emitted. In the present exemplary embodiment, the light emitting device 40 is directly installed in the cavity 11, formed on the heat dissipating substrate 10, and heat generated by the light emitting device 40 can be directly radiated by the heat dissipating substrate 10, thereby reducing the number of the components and the manufacturing processes. Also, the light emitting device package is formed of materials having a high thermal conductivity, thereby embodying a notably low heat resistance and improving the heat dissipating function.

The first conductive pattern 20 formed on the bottom surface and the inner side of the cavity 11 functions as a conductor as well as a reflector and a process of patterning the inside of the cavity 11 is excluded, thereby facilitating manufacturing, and improving a reflection property because the entire surface of the cavity 11 can be used as a reflective surface.

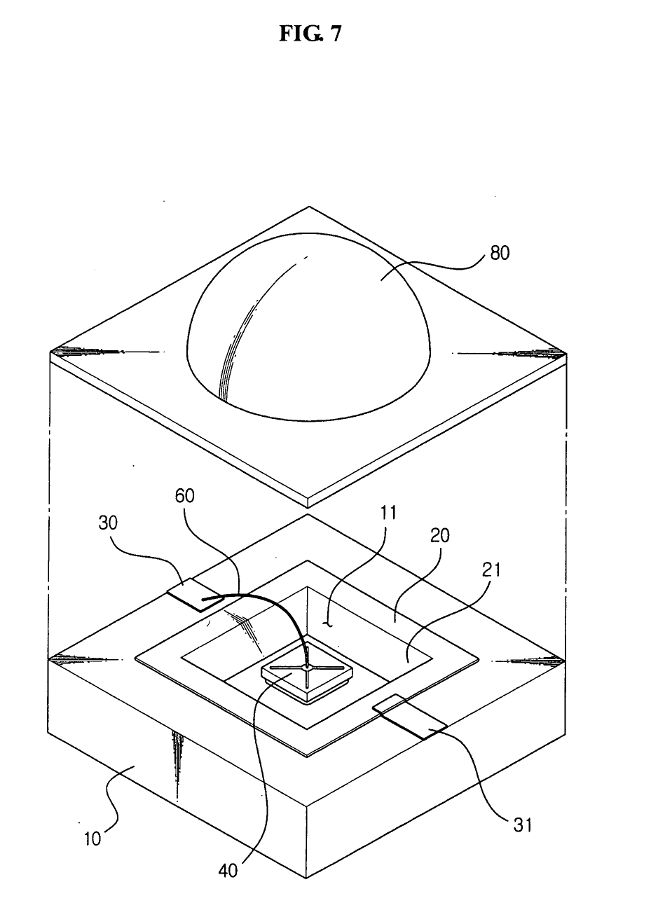

FIG. 7 is a perspective view illustrating a light emitting device package according to a fourth exemplary embodiment of the present invention.

In the previous exemplary embodiments, the cavity 11 is formed in the shape of a circular truncated cone having a cross-section which expands toward the top. According to circumstances, as shown in FIG. 7, the cavity 11 may be formed in the shape of a frustum of a pyramid having a cross-section which expands toward the top.

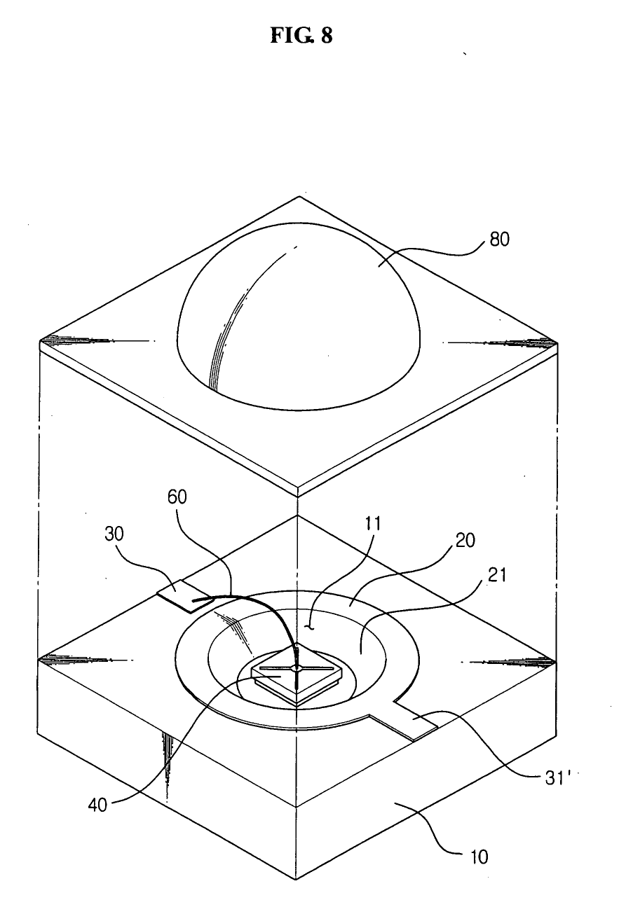

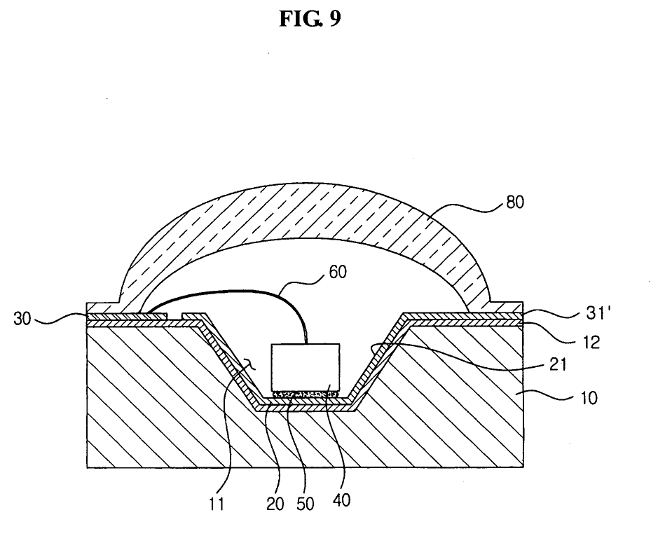

FIG. 8 is a perspective view illustrating a light emitting device package according to a fifth exemplary embodiment of the present invention, and FIG. 9 is a cross-sectional view illustrating the light emitting device package according to the fifth exemplary embodiment of the present invention.

As shown in FIGS. 8 and 9, in the light emitting device package according to the fifth exemplary embodiment of the present invention, a connecting conductive pattern 31′ extends from the first conductive pattern and forms a single body with the first conductive pattern.

Namely, the connecting conductive pattern 31′ is formed from an extension of an edge of the first conductive pattern 20 on the top surface of the insulating layer 12 corresponding to the top surface of the heat dissipating substrate 10. The connecting conductive pattern 31′ may be formed integrally with the first conductive pattern 20 when the first conductive pattern 20 is formed.

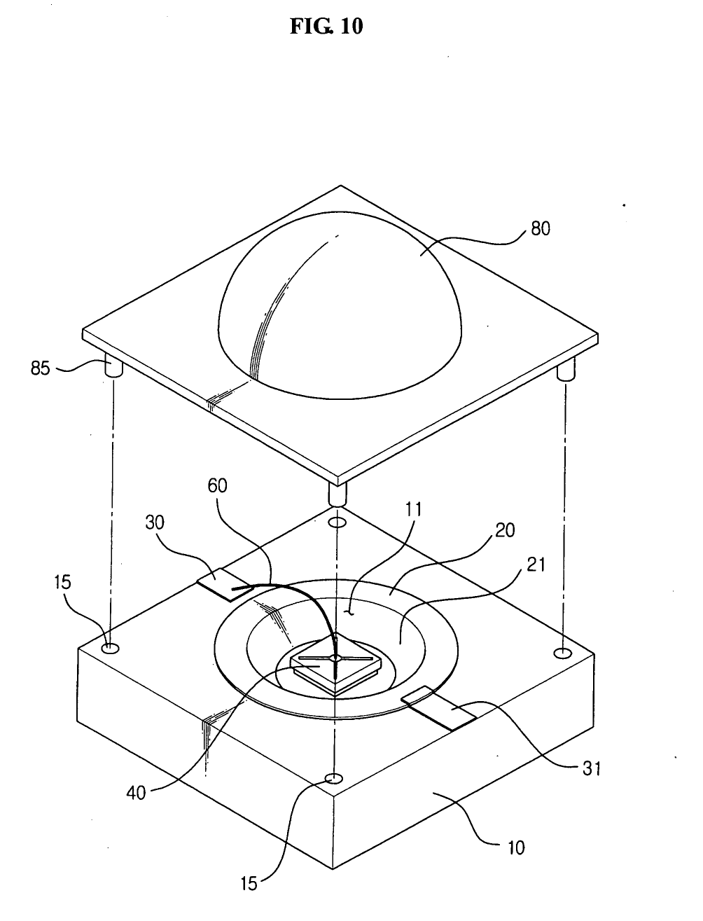

FIG. 10 is a perspective view illustrating a light emitting device package according to a sixth exemplary embodiment of the present invention. As shown in FIG. 10, a plurality, of projections 85 may be formed on a bottom surface of the lens 80. On the top surface of the heat dissipating substrate 10, opposite to the bottom surface of the lens 80, a plurality of grooves 15 may be formed to receive each of the plurality of projections 85. The plurality of projections 85 and the plurality of grooves 15 enables the lens 80 to be coupled easily with the heat dissipating substrate 10 and enables the coupling to be stable. In the present exemplary embodiment, the projections 85 are formed on the bottom surface of the lens 80 and the grooves 15 are formed on the top surface of the heat dissipating substrate 10. However, alternately, the grooves may be formed on the bottom surface of the lens 80 and the projections 85 may be formed on the top surface of the heat dissipating substrate 10.

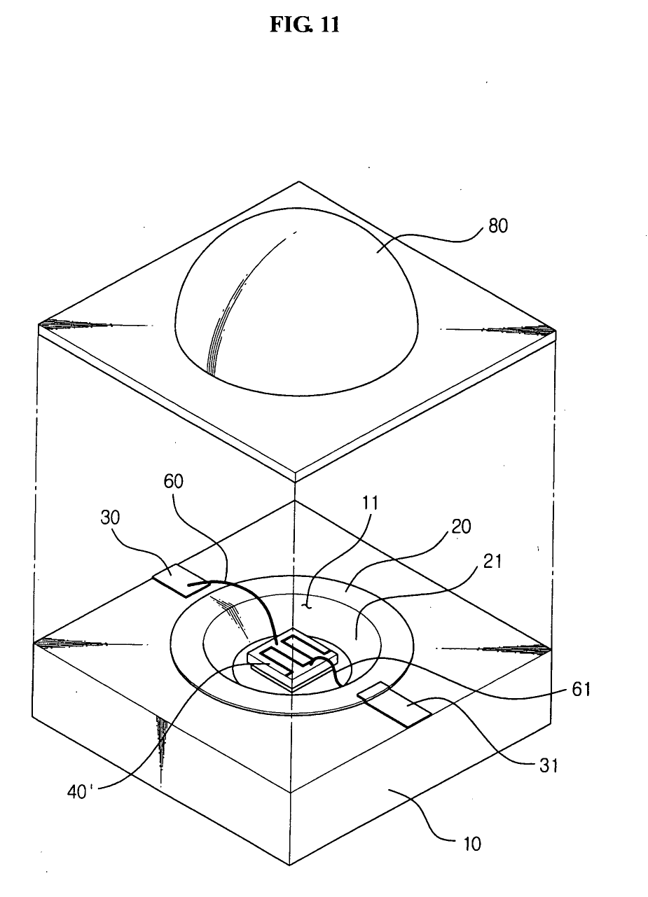

FIG. 11 is a perspective view illustrating a light emitting device package according to a seventh exemplary embodiment of the present invention.

As shown in FIG. 11, the light emitting device package according to the seventh exemplary embodiment of the present invention includes the heat dissipating substrate 10 formed of a metal on which the insulating layer 12 (see FIGS. 3-6 and 9) is formed on the surface thereof and including the cavity 11, and the first conductive pattern 20 formed on the cavity 11. A light emitting device 40′ is installed on the first conductive pattern 20, and the second conductive pattern 30 is formed on the periphery of the first conductive pattern 20 and is electrically separated from the first conductive pattern 20. The second conductive pattern supplies the power required for operating the light emitting device 40′. The first bonding wire 60 electrically connects the light emitting device 40′ and the second conductive pattern 30, and a second bonding wire 61 electrically connects the light emitting device 40′ and the first conductive pattern 20. Ends of the first and second bonding wires may be bonded on the same surface of the light emitting device, respectively.

The described exemplary embodiment of the present invention may be applied when the light emitting device 40′, having a horizontal electrode structure, is connected to the first and second conductive patterns 20 and 30 via the first and second bonding wires 60 and 61.

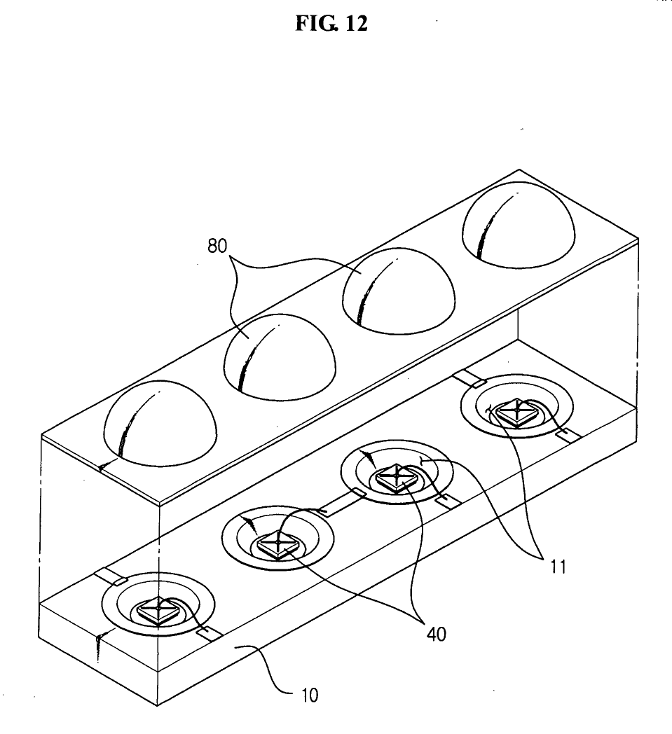

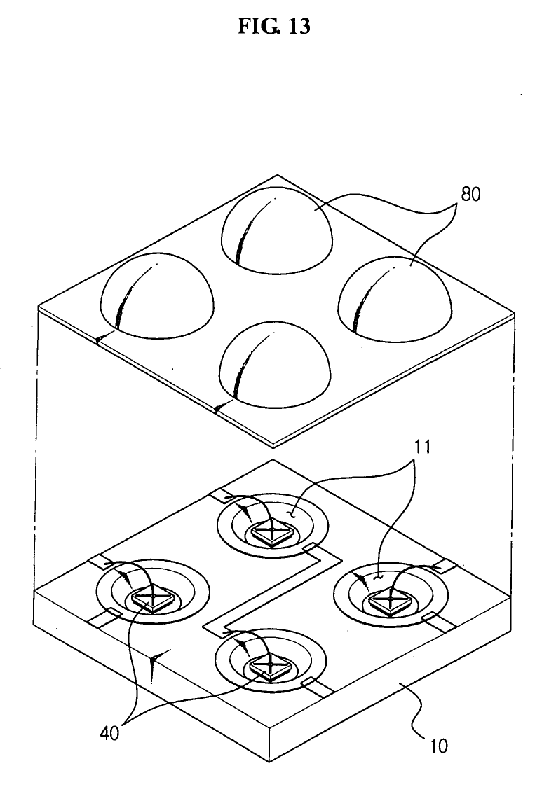

FIGS. 12 and 13 are perspective views illustrating a light emitting device package according to an eighth exemplary embodiment of the present invention.

In each of the described exemplary embodiments, one light emitting device 40 is installed on the heat dissipating substrate 10. However, as shown in FIGS. 12 and 13, a plurality of the cavities 11 may be formed on the heat dissipating substrate 10, and may be separated from each other at a certain interval. A plurality of the light emitting devices 40 may be formed in conjunction with the plurality of the cavities 11. In this case, the light emitting devices 40 may be disposed in a line to form a line source formed in the shape of a bar as shown in FIG. 12. Alternately, the light emitting devices 40 may be disposed in an N×N array to embody a flat fluorescent lamp formed in the shape of a plate as shown in FIG. 13, and may be connected in series when the light emitting devices 40 emit the same color.

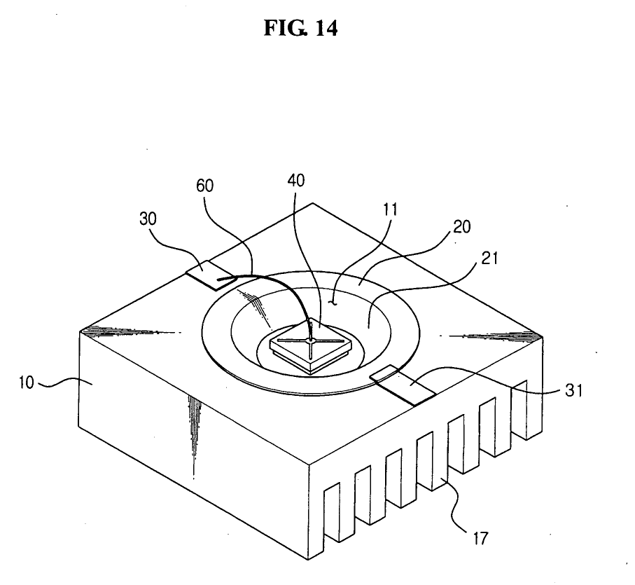

FIG. 14 is a perspective view illustrating a light emitting device package according to a ninth exemplary embodiment of the present invention. As shown in FIG. 14, a heat sink 17 may be integrated with the heat dissipating substrate 10 to improve the radiation of heat.

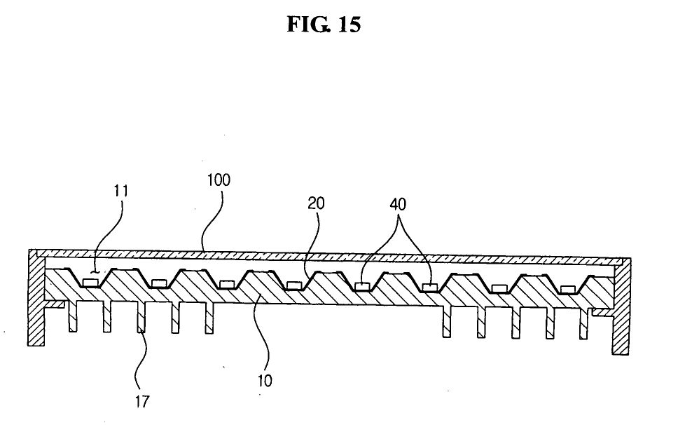

FIG. 15 is a perspective view illustrating a light emitting device package according to a tenth exemplary embodiment of the present invention.

The light emitting device package according to the present exemplary embodiment may be used as a general lighting device as well as a backlight unit that supplies light for a liquid crystal panel 100 of a liquid crystal display.

In addition, in the present exemplary embodiment, the light emitting device package uses a direct emitting type which emits light upwardly. However, the light emitting device package may be alternately use a side-emitting type.

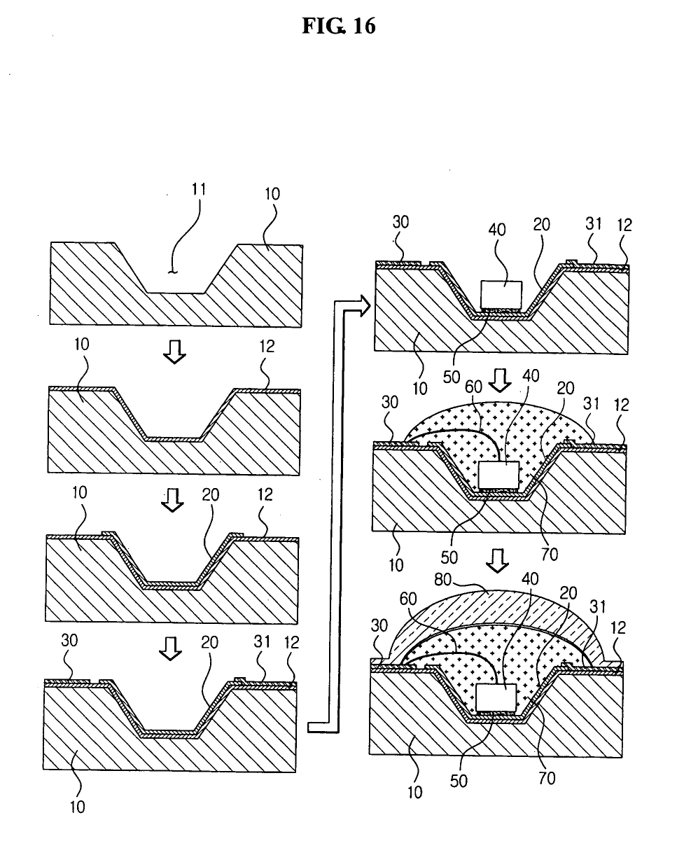

FIGS. 16 through 18 illustrate a method of manufacturing a light emitting device package according an exemplary embodiment of the present invention.

As shown in FIG. 16, the method of manufacturing the light emitting device package according to the present exemplary embodiment includes the operations of providing the heat dissipating substrate 10 including the cavity 11, forming the insulating layer 12 on the substrate, forming the first conductive pattern 20 on the cavity 11, forming the second conductive pattern 30 on the periphery of the first conductive pattern 20 (electrically separated from the first conductive pattern 20), and installing the light emitting device 40 on the first conductive pattern 20.

The heat dissipating substrate 10 is formed of a metal such as aluminum or an aluminum alloy. The cavity 11 is formed on the top surface of the heat dissipating substrate 10.

The cavity 11 may be formed by mechanical processing or by etching. The insulating layer 12 is formed on the surface of the heat dissipating substrate 10, including the surface of the cavity 11, after forming the cavity 11.

The insulating layer 12 may be formed by forming an oxidized layer (Al₂O₃) on the surface of the heat dissipating substrate 10 formed of aluminum or an aluminum alloy via an anodizing process. The insulating layer 12 may be formed to be an additional polymer based insulating layer.

After forming the first conductive pattern 20 on the insulating layer 12 in the cavity 11, the second conductive pattern 30 is formed on the periphery of the first conductive pattern 20 and is electrically separated from the first conductive pattern 20. When forming the second conductive pattern 30, the connecting conductive pattern 31 may be formed on the top surface of the insulating layer 12, corresponding to the top surface of the heat dissipating substrate 10, to be electrically connected to the first conductive pattern 20.

The light emitting device 40 is installed on the first conductive pattern 20 to be electrically connected to each of the first and second conductive patterns 20 and 30, thereby completing the process of manufacturing the light emitting device package.

The operation of installing the light emitting device 40 includes an operation of interposing the electro-conductive adhesive layer 50 between the light emitting device 40 and the first conductive pattern 20. Via the described process, the light emitting device 40 may be electrically connected to the first conductive pattern 20. Also, the second conductive pattern 30 may be electrically connected to the light emitting device 40 via the first bonding wire 60.

On the other hand, the light emitting device 40′ of FIG. 11, connected to each of the first and second conductive patterns 20 and 30 in a horizontal connection structure may be electrically connected to the first conductive pattern 20 via the first bonding wire 60 and may be electrically connected to the second conductive pattern 30 via the second bonding wire 61. In this case, each of the first and second bonding wires 60 and 61 may be bonded on the same surface of the light emitting device 40′.

In addition, in the present exemplary embodiment, the first conductive pattern 20 is formed before forming the second conductive pattern 30. However, the second conductive pattern 30 may be formed before forming the first conductive pattern 20, and the scope of the present invention is not limited by the above-described manufacturing order.

In addition, the first conductive pattern 20 may be formed by a process as follows.

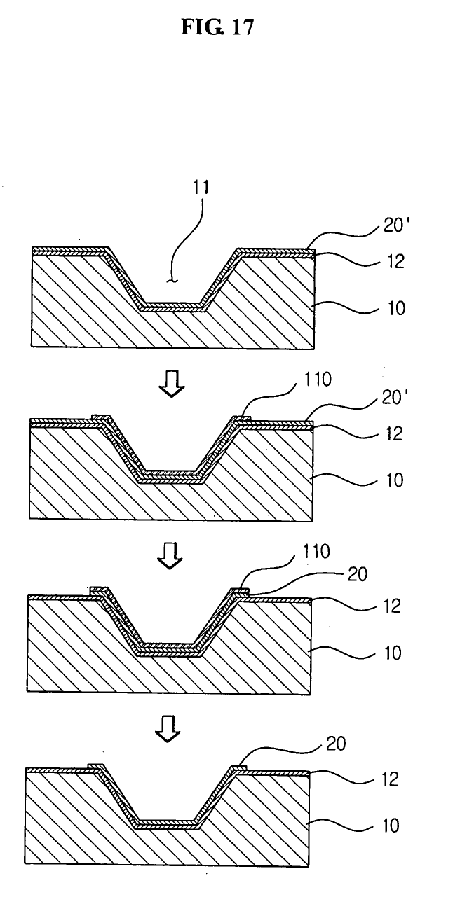

As shown in FIG. 17, a method of manufacturing the first conductive pattern 20 includes the operations of forming a conductive layer 20′ (a conductive material formed on the surface of the insulating layer 12), forming a mask pattern 110 on the conductive layer 20′, removing a part of the conductive layer 20′ via the mask pattern 110, and removing the mask pattern 110.

Namely, after forming the conductive layer 20′ formed of an electro-conductive material such as aluminum and silver, on the surface of the insulating layer 12, the mask pattern 110 is patterned on the surface of the conductive layer 20′ corresponding to the surface of the cavity 11. In this case, the conductive layer 20′ may be formed via vapor deposition or plating and the mask pattern 110 may be formed of a photosensitive material.

Other portions of the conductive layer 20′, excluding the portion where the mask pattern 110 is patterned, are removed by etching. Finally, manufacturing the first conductive pattern 20 may be completed by removing the mask pattern 110.

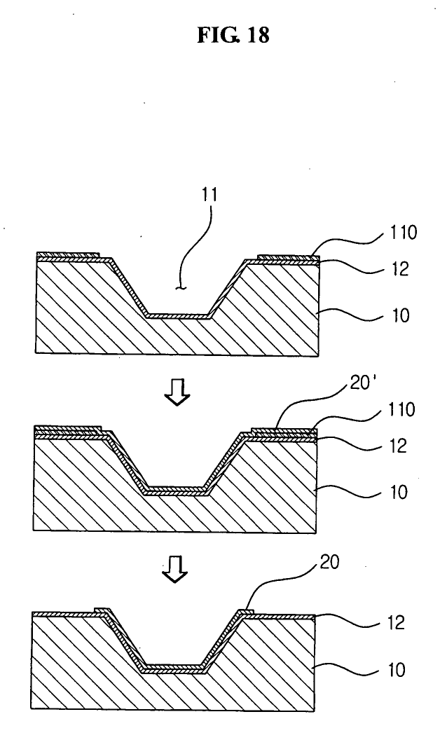

As shown in FIG. 18, another method of manufacturing the conductive pattern 20 includes the operations of forming the mask pattern 110 on the surface of the insulating layer 12, forming the conductive layer 20′ (a conductive material formed on a surface of the mask pattern 110 and the surface of the insulating layer 12), and removing the mask pattern 110 and a part of the conductive layer 20′ overlaid on the mask pattern 110.

The mask pattern 110 formed of the photosensitive material is patterned on the surface of the insulating layer 12 excluding the surface of the cavity 11, and the conductive layer 20′ formed of the electro-conductive material, such as aluminum or silver, is formed on the surface of the mask pattern 110 and the surface of the insulating layer 12. The conductive layer 20′ may be also formed by deposition or plating.

After that, the mask pattern 110 and the part of the conductive layer 20′ overlaid on the mask pattern 110 are removed, thereby completing the manufacture of the first conductive pattern 20. Namely, in this case, the part of the conductive layer 20′ overlaid on the mask pattern 110 is removed as the mask pattern 110 is removed, and finally, the first conductive pattern 20 may be formed on a part corresponding to the surface of the cavity 11.

On the other hand, the first conductive pattern 20 may be formed of a single or a multiple metal layer of electro-conductive material such as aluminum, copper, chrome, titanium, platinum, or silver (see FIGS. 2 and 3). The surface of the first conductive pattern 20 itself, may be a reflective surface, and a reflective coating layer formed of a reflective material such as silver may be formed on the top surface of the first conductive pattern 20. Also, an additional protection layer 23 may be formed on a part of the surface of the first conductive pattern 20 to be electrically connected to the first bonding wire 60 (refer to 23 of FIG. 6).

Also, in the operation of providing the heat dissipating substrate 10, the heat sink 17 may be integrated with the heat dissipating substrate 10 (see FIGS. 11 and 12). After electrically connecting the first and second conductive patterns 20 and 30 to the light emitting device 40, the transparent resin 70 may be applied onto the heat dissipating substrate 10 including the cavity 11, and the lens 80 may be coupled with the heat dissipating substrate 10 to cover the opening portion of the cavity 11. In this case, the transparent resin 70 may include a fluorescent material to convert the light generated from the light emitting device 40 into other wavelengths and may be applied to fill a part or an entirety of the space formed between the heat dissipating substrate 10 and the lens 80.

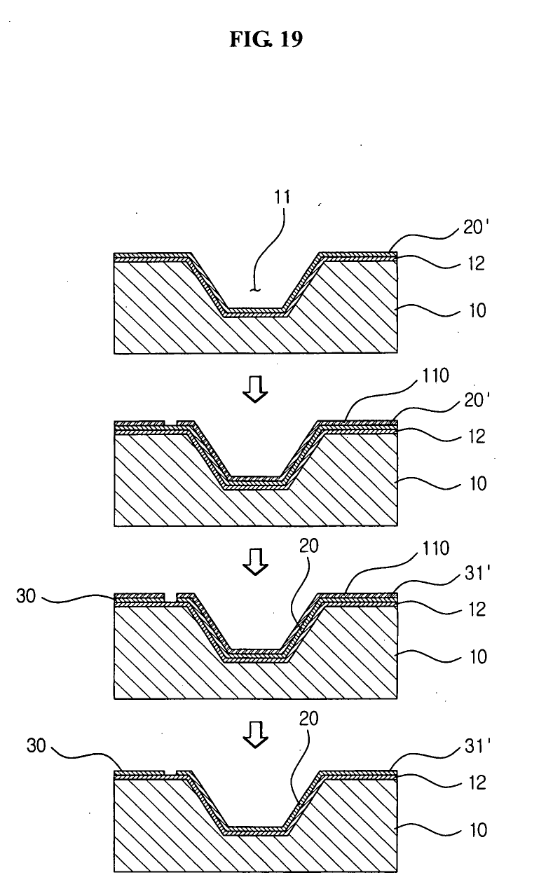

FIG. 19 illustrates a method of manufacturing a light emitting device package according to another exemplary embodiment of the present invention.

As shown in FIG. 19, the method of manufacturing the light emitting device package according to another exemplary embodiment of the present invention includes the operations of providing the heat dissipating substrate 10, formed of a metal and including the cavity 11, forming the insulating layer 12 is on the surface of the heat dissipating substrate 10, forming the conductive layer 20′ (an electro-conductive material) on the surface of the insulating layer 12, forming the mask pattern 110 on the surface of the conductive layer 20′, forming the first conductive pattern 20 and the second conductive pattern 30 by removing a part of the conductive layer 20′ via the mask pattern 110, removing the mask pattern 110, and the installing the light emitting device on the first conductive pattern 20.

In the described method of manufacturing the light emitting device package according to another exemplary embodiment of the present invention, the first conductive pattern 20 and the second conductive pattern 30 may be formed in a single process.

Namely, after forming the conductive layer 20′, formed of an electro-conductive material such as aluminum or silver, on the surface of the insulating layer 12, the mask pattern 110 is patterned to divide and partition the surface of the conductive layer 20′ into a certain pattern. In this case, the conductive layer 20′ may be formed by deposition or plating, and the mask pattern 110 may be formed of a photosensitive material.

After that, a part of the conductive layer 20′, excluding a part in which the mask pattern 110 is patterned, is removed, and the mask pattern 110 is removed, thereby forming the first conductive pattern 20 and the second conductive pattern 30.

Next, the light emitting device 40 is installed on the first conductive pattern 20 and is electrically connected to the first and second conductive patterns 20 and 30, thereby completing the manufacture of the light emitting device package.

Also, in the operation of forming the first and second conductive patterns 20 and 30, the connecting conductive pattern 31′ may be formed to be extended from the first conductive pattern 20.

As described above, according to exemplary embodiments of the present invention, a light emitting device package and a method of manufacturing the same are provided, in which a light emitting device is directly installed on a cavity formed on a heat dissipating substrate to directly radiate heat generated from the light emitting device via the heat dissipating substrate, thereby preventing overheating of the light emitting device as well as performance deterioration, lifespan reduction, and discoloration of the light emitting device caused by overheating.

Particularly, the heat dissipating substrate is formed of a material having a high thermal conductivity to reduce heat resistance, thereby improving heat dissipation.

According to exemplary embodiments of the present invention, a light emitting device package having a simple structure is also provided, thereby providing a more simplified light emitting device package.

According to exemplary embodiments of the present invention, a light emitting device package including a reflective surface to improve a reflective property is also provided, thereby minimizing loss of light and obtaining a high brightness property for the same light source condition.

According to exemplary embodiments of the present invention provide a light emitting device package in which a plurality of light emitting devices are installed on a heat dissipating substrate to be integrated, thereby sharply simplifying a process of manufacturing the light emitting device package to be advantageous for mass production and reducing a number of components and manufacturing processes to reduce a manufacturing cost and reduce other costs.

Although a few exemplary embodiments of the present invention have been shown and described, the present invention is not limited to the described exemplary embodiments. Instead, it would be appreciated by those skilled in the art that changes may be made to these exemplary embodiments without departing from the principles and spirit of the invention, the scope of which is defined by the claims and their equivalents.

What is claimed is:

1. A light emitting device package comprising:
a heat dissipating substrate including a cavity;
a first conductive pattern disposed on the cavity;
a light emitting device disposed on the first conductive pattern; and
a second conductive pattern disposed on the heat dissipating substrate at a periphery of the first conductive pattern;
wherein the second conductive pattern is electrically separated from the first conductive pattern and wherein the first conductive pattern and the second conductive pattern supply power required for operating the light emitting device.

2. The package of claim 1, wherein the heat dissipating substrate is a metal, and wherein the package further comprises an insulating layer disposed on a surface of the heat dissipating substrate.

3. The package of claim 2, wherein the heat dissipating substrate is aluminum or an aluminum alloy, and the insulating layer is an oxidized layer.

4. The package of claim 1, wherein the first conductive pattern comprises a reflective surface, which is optically treated, formed at a periphery of the light emitting device.

5. The package of claim 4, wherein the reflective surface is optically treated by adding a reflective coating layer on the first conductive pattern.

6. The package of claim 1, wherein the first conductive pattern comprises a single metal layer or multiple metal layers of an electro-conductive material.

7. The package of claim 1, wherein the first conductive pattern is entirely disposed on a bottom and sides of the cavity.

8. The package of claim 1, further comprising a connecting conductive pattern, disposed on the heat dissipating substrate, which is electrically connected to the first conductive pattern.

9. The package of claim 8, wherein the connecting conductive pattern extends from the first conductive pattern as a signal body.

10. The package of claim 1, further comprising a first bonding wire which electrically connects the light emitting device and the second conductive pattern.

11. The package of claim 10, further comprising a second bonding wire which electrically connects the light emitting device and the first conductive pattern.

12. The package of claim 1, wherein an adhesive layer, comprising an electro-conductive material, is interposed between the light emitting device and the first conductive pattern, thereby electrically connecting the light emitting device and the first conductive pattern.

13. The package of claim 1, further comprising a protection layer which electrically insulates at least one of a surface of the first conductive pattern and a surface of the first bonding wire.

14. The package of claim 1, further comprising a heat sink formed as a single body on the heat dissipating substrate.

15. The package of claim 1, further comprising a lens disposed above the cavity.

16. The package of claim 15, further comprising a transparent resin filling a part or an entirety of a space formed between the cavity and the lens.

17. The package of claim 15, further comprising at least one projection formed on any one of mutual contact surfaces of the lens and the radiating substrate, and at least one corresponding groove formed on the other surface of the mutual contact surfaces of the lens and the heat dissipating substrate, to contain the projection.

18. The package of claim 1, wherein:
a plurality of the cavities are separated from each other at a predetermined interval; and
a plurality of the light emitting devices are formed corresponding to each of the cavities.

19. A light emitting device package comprising:
a heat dissipating substrate, formed of a metal, including a cavity therein;
an oxidized layer formed on a surface of the heat dissipating substrate
a first conductive pattern, comprising a reflecting surface formed by reflection processing, disposed on the cavity;
a connecting conductive pattern disposed on the heat dissipating substrate, which is electrically connected to the first conductive pattern;
a light emitting device installed on the first conductive pattern; and
a second conductive pattern disposed on the heat dissipating substrate at a periphery of the first conductive pattern;
wherein the second conductive pattern is electrically separated from the first conductive pattern and wherein the first conductive pattern and the second conductive pattern supply power required for operating the light emitting device.

20. A method of manufacturing a light emitting device package, the method comprising:
providing a heat dissipating substrate having a cavity therein;
forming a first conductive pattern on the cavity;
forming a second conductive pattern on the heat dissipating substrate at a periphery of the first conductive pattern, wherein the second conductive pattern is electrically separated from the first conductive pattern; and
installing a light emitting device on the first conductive pattern.

21. The method of claim 20, wherein the heat dissipating substrate comprises a metal, and the method further comprises forming an insulating layer is on a surface thereof of the heat dissipating substrate.

22. The method of claim 21, wherein the metal is aluminum or an aluminum alloy, and the insulating layer is an oxidized layer made by anodizing.

23. The method of claim 21, wherein the forming a first conductive pattern comprises:
forming a conductive layer, comprising a conductive material, on a surface of the insulating layer;
forming a mask pattern on the conductive layer;
removing a part of the conductive layer by using the mask pattern; and
removing the mask pattern.

24. The method of claim 21, wherein the forming a first conductive pattern comprises:
forming a mask pattern on a surface of the insulating layer;
forming a conductive layer, comprising a conductive material, on the mask pattern and the insulating layer; and
removing the mask pattern and a part of the conductive layer overlaid on the mask pattern.

25. The method of claim 20, wherein the first conductive pattern comprises a single metal layer or multiple metal layers of an electro-conductive material.

26. The method of claim 20, wherein the forming a first conductive pattern further comprises forming a reflective coating layer, comprising a reflecting material, on a top of the first conductive pattern.

27. The method of claim 20, further comprising electrically connecting the light emitting device and the second conductive pattern via a first bonding wire.

28. The method of claim 27, further comprising electrically connecting the light emitting device and the first conductive pattern via a second bonding wire.

29. The method of claim 27, further comprising forming a protection layer on at least one of a surface of the first conductive pattern, and a surface of the first bonding wire, thereby electrically insulating the at least one of a surface of the first conductive pattern and a surface of the first bonding wire.

30. The method of claim 20, wherein the installing the light emitting device comprises interposing an electro-conductive adhesive layer between the light emitting device and the first conductive pattern.

31. The method of claim 20, wherein the providing a heat dissipating substrate comprises forming a heat sink as a single body on the heat dissipating substrate.

32. The method of claim 20, further comprising filling a part or an entirety of a space formed between the heat dissipating substrate including the cavity and a lens with a transparent resin.

33. The method of claim 32, further comprising coupling the lens with the heat dissipating substrate, thereby covering the cavity.

34. A method of manufacturing a light emitting device package, the method comprising:
providing a heat dissipating substrate, comprising a base metal, including a cavity therein;
forming an insulating layer on a surface of the heat dissipating substrate
forming a conductive layer, comprising a conductive material, on a surface of the insulating layer;
forming a mask pattern on a surface of the conductive layer;
forming a first conductive pattern and a second conductive pattern by removing a part of the conductive layer by using the mask pattern;
removing the mask pattern; and
installing a light emitting device on the first conductive pattern.

35. The method of claim 34, wherein the forming a first conductive pattern and a second conductive pattern comprises forming a connecting conductive pattern as a single body with the first conductive pattern.
